(19) United States
(12) Patent Application Publication
(10) Pub. No.: US 2013/0278289 A1
(43) Pub. Date: Oct. 24, 2013

(54) Method and Apparatus for Improving Efficiency of Programmable Logic Circuit Using Cascade Configuration

(71) Applicants: Te-Tse Jang, San Jose, CA (US); James F. Rogers, Pleasanton, CA (US)

(72) Inventors: Te-Tse Jang, San Jose, CA (US); James F. Rogers, Pleasanton, CA (US)

(21) Appl. No.: 13/865,851

(22) Filed: Apr. 18, 2013

Related U.S. Application Data
(60) Provisional application No. 61/635,283, filed on Apr. 18, 2012.

(51) Int. Cl. H03K 19/173

(52) U.S. Cl. CPC H03K 19/173
USPC 326/38

(57) ABSTRACT

An integrated circuit (“IC”) device capable of programmably performing user selected functions is disclosed. The IC device, in one embodiment, includes multiple input output (“I/O”) blocks, programmable interconnection blocks (“PIBs”), and programmable logic blocks (“PLBs”). While the I/O blocks can be selectively coupled to one of I/O pads, the PIB blocks can be selectively coupled to at least a portion of the I/O blocks. Each of the PLBs, in one aspect, is configured to have at least two programmable look-up tables (“LUTs”). The programmable LUTs are connected in a cascade configuration via a dedicated programmable wire (“DPW”).

### PRIORITY

This application claims the benefit of priority based upon U.S. Provisional Patent Application Ser. No. 61/635,283, filed on Apr. 18, 2012 and entitled “Method and Apparatus for Providing Look-up Tables (“LUTs”) using Cascade Configuration,” all of which are hereby incorporated herein by reference in their entireties.

### FIELD OF THE INVENTION

The exemplary embodiment(s) of the present invention relates to the field of semiconductor and integrated circuits. More specifically, the exemplary embodiment(s) of the present invention relates to semiconductor circuits having programmable capabilities.

### BACKGROUND OF THE INVENTION

To implement a set of desirable logic functions, an integrated circuit (“IC”) designer typically uses variety of options or approaches to achieve such functions using, for instance, conventional semiconductor ICs. Conventional semiconductor IC, for example, includes application-specific ICs (“ASICs”) and/or programmable logic devices (“PLDs”) or field programmable gate arrays (“FPGAs”). ASIC is a semiconductor fabricated chip typically containing various circuits specifically customized or configured to perform a designated set of function(s) and/or purpose(s). ASIC chips generally provide efficient performance with fast clock cycles. Since ASIC is customized for a particular functionality, a drawback associated with the ASIC chip is unalterable after the chip is fabricated.

PLDs or FPGA, on the other hand, is alterable after the chip is fabricated because it can be programmed to perform a user designated specific function. A typical PLD or FPGA includes multiple programmable logic blocks, routing resources, and input/output (“I/O”) pins. Each of the programmable logic blocks generally contains multiple programmable look-up tables (“LUTs”) as basic building blocks to perform user defined function(s). Although PLD or FPGA is more versatile or flexible, it is typically high cost (large die size), high power consumption, and relatively low performance partially because it carries flexible logic blocks as well as programmable interconnection arrays (“PIAs”).

In mapping a synthesized logic design into programmable LUTs, a limitation is number of inputs that a LUT can handle. The number of inputs or number of input terminal of a LUT, also known as “size of LUT” or “LUT size,” may essentially determine how sophisticated logic functions can be performed. Implementing logic functions with more inputs than that basic LUT width requires connecting multiple layers of LUTs through the programmable fabric interconnect network or PIA. The programmable routing resource, PIA, or programmable fabric interconnect network typically include multiple levels of multiplexers (“muxes”).

A problem associated with using multiple levels of muxes is that the delay generated by the multiple levels of muxes for a signal to pass creates timing failures for various logic operations. Timing failure typically renders device failure. A conventional approach to mitigate this program is to use a larger LUT with added input terminals so that it can receive large number inputs. A problem, however, associated with the larger LUT is that it generally occupies large area of semiconductor die. Note that the increasing in die area for a larger LUT is a steep increase (as an exponential function) with respect to increasing in number of input terminals for a larger LUT.

### SUMMARY

One embodiment of the present application discloses an integrated circuit (“IC”) device capable of programmably performing user selected functions. The IC device, in one embodiment, includes multiple input output (“I/O”) blocks, programmable interconnection block (“PIB”), and programmable logic blocks (“PLBs”). While the I/O blocks can be selectively coupled to one of I/O pads, the PIB blocks can be programmably coupled to at least a portion of the I/O blocks. The PLBs, in one embodiment, provide selectable logic functions. Each of the PLBs, in one aspect, is configured to have at least two programmable look-up tables (“LUTs”). The programmable LUTs, in one embodiment, are configured in a cascade configuration via a dedicated programmable wire (“DPW”).

Additional features and benefits of the present invention will become apparent from the detailed description, figures and claims set forth below.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIGS. 1A-B are block diagrams illustrating programmable integrated circuit (“IC”) device able to enhance routing capability using a cascade configuration in accordance with one embodiment of the present invention;

FIGS. 2A-C are block diagrams illustrating a cascade configuration using two six-input terminals LUTs in accordance with one embodiment of the present invention;

FIG. 3 is a block diagram illustrating an alternative layout of cascade configuration showing a convergent approach using two priority inputs in accordance with one embodiment of the present invention;

FIG. 4 is a block diagram illustrating an alternative layout for a convergent cascade configuration using four (4) six-input terminal LUTs in accordance with one embodiment of the present invention;

FIG. 5 is a block diagram illustrating a cascade configuration organized in a continuous chain layout in accordance with one embodiment of the present invention;

FIG. 6 is a diagram illustrating a multi-level convergent cascade for programmable LUTs in accordance with one embodiment of the present invention;

FIG. 7 is a diagram illustrating a layout of two 3-LUT groups converging on a seventh LUT in accordance with one embodiment of the present invention;

FIGS. 8A-B are block diagrams illustrating cascade maps or logical layout within a PLB logic in accordance with one embodiment of the present invention;

FIG. 9 is a diagram illustrating an example of digital processing system including programmable IC device using LUT cascade configuration in accordance with one embodiment of the present invention; and

FIG. 10 is a flow chart illustrating a process of cascading multiple LUTs using dedicated connections to perform logic functions in accordance with one embodiment of the present invention.

### DETAILED DESCRIPTION

Exemplary embodiment(s) of the present invention is described herein in the context of a method, device, and/or apparatus for enhancing routing capability to a programmable integrated circuit (“IC”) using a cascade configuration of logic elements.

Those of ordinary skilled in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the exemplary embodiments of the present invention as illustrated in the accompanying drawings. The same reference indicators (or numbers) will be used throughout the drawings and the following detailed description to refer to the same or like parts.

In accordance with the embodiment(s) of present invention, the components, process steps, and/or data structures described herein may be implemented using various types of operating systems, computing platforms, computer programs, and/or general purpose machines. In addition, those of ordinary skills in the art will recognize that devices of a less general purpose nature, such as hardwired devices, field programmable gate arrays (FPGAs), application specific integrated circuits (ASICs), or the like, may also be used without departing from the scope and spirit of the inventive concepts disclosed herein. Where a method comprising a series of process steps is implemented by a computer or a machine and those process steps can be stored as a series of instructions readable by the machine, they may be stored on a tangible medium such as a computer memory device (e.g., ROM (Read Only Memory), PROM (Programmable Read Only Memory), EEPROM (Electrically Erasable Programmable Read Only Memory), FLASH Memory, Jump Drive, and the like), magnetic storage medium (e.g., tape, magnetic disk drive, and the like), optical storage medium (e.g., CD-ROM, DVD-ROM, paper card and paper tape, and the like) and other known types of program memory.

The term “system” is used generically herein to describe any number of components, elements, sub-systems, devices, packet switch elements, packet switches, routers, networks, computer and/or communication devices or mechanisms, or combinations of components thereof. The term “computer” is used generically herein to describe any number of computers, including, but not limited to personal computers, embedded processors and systems, control logic, ASICs, chips, workstations, mainframes, etc. The term “device” is used generically herein to describe any type of mechanism, including a computer or system or component thereof. The terms “task” and “process” are used generically herein to describe any type of running program, including, but not limited to a computer process, task, thread, executing application, operating system, user process, device driver, native code, machine or other language, etc., and can be interactive and/or non-interactive, executing locally and/or remotely, executing in foreground and/or background, executing in the user and/or operating system address spaces, a routine of a library and/or standalone application, and is not limited to any particular memory partitioning technique. The steps, connections, and processing of signals and information illustrated in the figures, including, but not limited to the block and flow diagrams, are typically performed in a different serial or parallel ordering and/or by different components and/or over different connections in various embodiments in keeping within the scope and spirit of the invention.

One embodiment of the present application discloses a programmable integrated circuit (“IC”) device capable of performing user selected functions using a cascade configuration of logic elements (“LE”). The Programmable IC device includes multiple input output (“I/O”) blocks, programmable interconnection array (“PIA”) or programmable interconnection blocks (“PIBs”), and programmable logic blocks (“PLBs”). While the I/O blocks can be selectively coupled to one of I/O pads, the PIBs can be selectively coupled to at least a portion of the I/O blocks. The PLBs can be configured to perform user selected logic functions. Each of the PLBs, in one aspect, includes at least two LEs or programmable look-up tables (“LUTs”). LEs and/or Programmable LUTs are herein referred to as LUTs. The LUTs are connected in a cascade configuration via a dedicated programmable wire (“DPW”). DPW can be programmed to a conductive state or a non-conductive state.

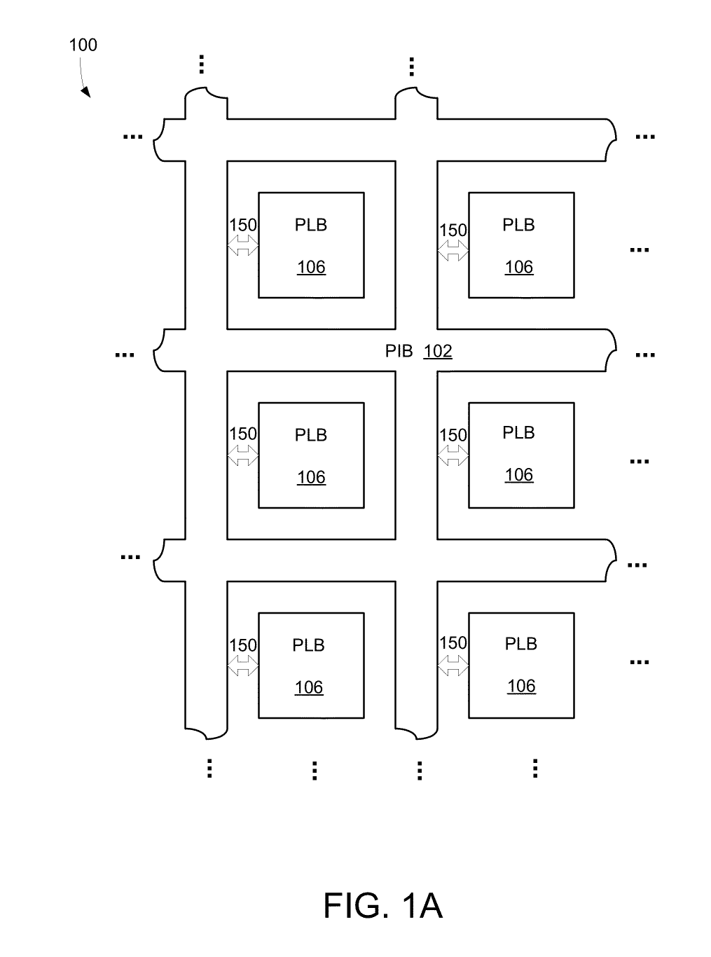

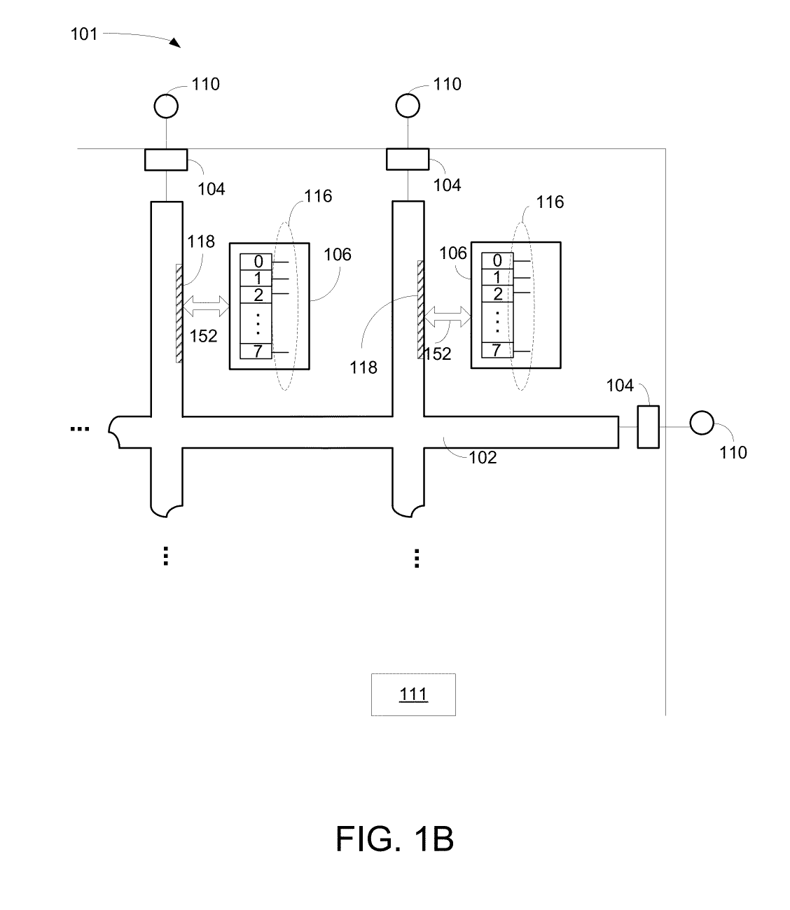

FIGS. 1A-B are block diagrams illustrating an exemplary layout of Programmable IC device 100 or 101 able to enhance routing capability using a cascade configuration in accordance with one embodiment of the present invention. Programmable IC device 100 includes multiple PLBs 106 and PIB 102. PLBs 106 are coupled to PIB 102 via buses or connections 150. In one example, Programmable IC device 100 can also be referred to as programmable logic devices (“PLDs”), field programmable gate arrays (“FPGAs”), programmable device, (“PD”), and the like. It should be noted that the underlying concept of the exemplary embodiment(s) of the present invention would not change if one or more blocks (or devices) were added to or removed from Programmable IC device 100.

PLB, also known as logic array block (“LAB”) or logic block (“LB”), includes, among other circuits, a group of LUTs and a DPW or DPWs. PLB 106, for example, includes various logic elements or LUTs wherein PLB 106, for example, includes eight (8) LUTs. Note that PLB 106 can contain additional LUTs and each PLB 106 can contain more than eight (8) LUTs or fewer than eight (8) LUTs.

LUTn is a logic building block capable of performing any arbitrarily defined n-inputs Boolean function, where n is the size of the LUT. LUT in PLB 106 is a basic building block of Programmable IC device 100.

PIB 102, which may be a network of programmable wires across entire chip for signal routing, is coupled to PLBs 106 using buses 150. Each bus may include a channel (or wire) or a set of channels. It should be noted that the terms channel, routing channel, wire, bus, connection, and/or interconnection mean similar element and will be used interchangeably herein. PIB 102 receives and transmits various signals directly or indirectly from and to I/O pins and PLBs 106. PIB 102, in one aspect, is arranged based on multiple levels of multiplexers, also known as a multiplexing structure or multiplexing connections. The multiplexers in PIB 102 are organized into multiple columns or levels. To improve routability, PIB 102 includes configurable multiplexers which can be further divided into multiple sections between adjacent or neighboring PLBs 106.

Depending on the applications, additional PLBs 106 can be added to programmable IC device 100. Similarly, if PLBs are added, PIB 102 will also need to be expanded to cover the routing requirement(s).

Programmable IC device 101, which illustrates a portion of device 100, includes multiple PLBs 106, PIB 102, I/O control units 104, and I/O pads 110. PLBs 106 are coupled to PIB 102 via buses or connections 152. PLB, in one aspect, includes, among other circuits, eight (8) LUTs and a DPW crossbar (“Dxbar”) 116. Note that PLB can contain additional LUTs. To simplify the forgoing description, eight (8) LUTs in each PLB are used.

Dxbar 116, in one embodiment, includes multiple DPWs, wherein each DPW can be selectively programmed to a state of conducting or state of non-conducting. Alternatively, some DPWs 118 may be hardwires without programmable capabilities. Dxbar 116, in one aspect, can be a part of routing resource situated around or in the vicinity of LUTs. Dxbar 116 can be a collection of individual wires used to facilitate formation of cascade configuration between LUTs. Note that DPWs 118 may be constructed as additional dedicated channels or wires in PIB 102 for facilitating LUT cascade configuration.

I/O control unit 104, coupled to PIB 102, is able to individually program various I/O pins or pads 110. Note that additional devices or connecting resource can be situated or placed between PIB 102 and I/O control unit 104. Some I/O pins 110 or pads 110 may be programmed as input pins while other I/O pins are configured as output pins. Also, some I/O pins 110 can be programmed as bi-directional pins that are capable of receiving and sending signals at the same time. In addition, I/O control unit 104 can provide clock signals to Programmable IC device 101. It should be noted that some I/O pins may be controlled by a digital processor or controller in Programmable IC device 101.

Programmable IC device 101 further includes a control logic 111 which is able to provide various programmable or control functions including, but not limited to, logic performance, channel assignment, differential I/O standards, and/or clock management. Control logic 111, which includes various components such as memory cells across the chip for configuration and controlling. Memory cells include volatile memory devices and non-volatile memory devices. For example, non-volatile memory devices include electrically erasable programmable read-only memory (“EEPROM”), erasable programmable read-only memory (“EPROM”), fuses, anti-fuses, magnetic RAM (“MRAM”), phase change devices, and/or flash memory. The volatile memory cells include SRAM, Dynamic Random Access Memory (“DRAM”), and ROM.

An advantage of using Dxbar 116 or DPWs 118 is that using DPWs to establish a cascade configuration of LUTs to substitute large LUTs with large number of inputs. As such, without fabricating large LUTs with large number of inputs can save die space thereby Programmable IC device can be more efficient in terms of speed, size, and density.

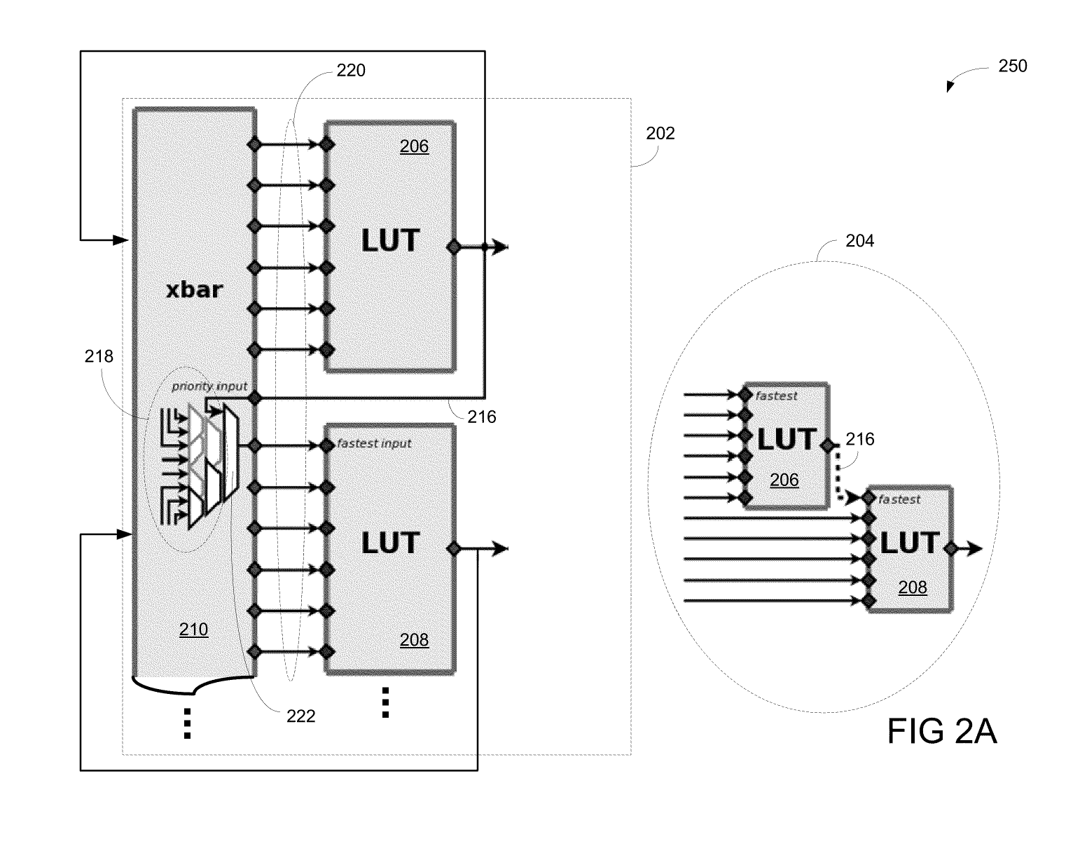

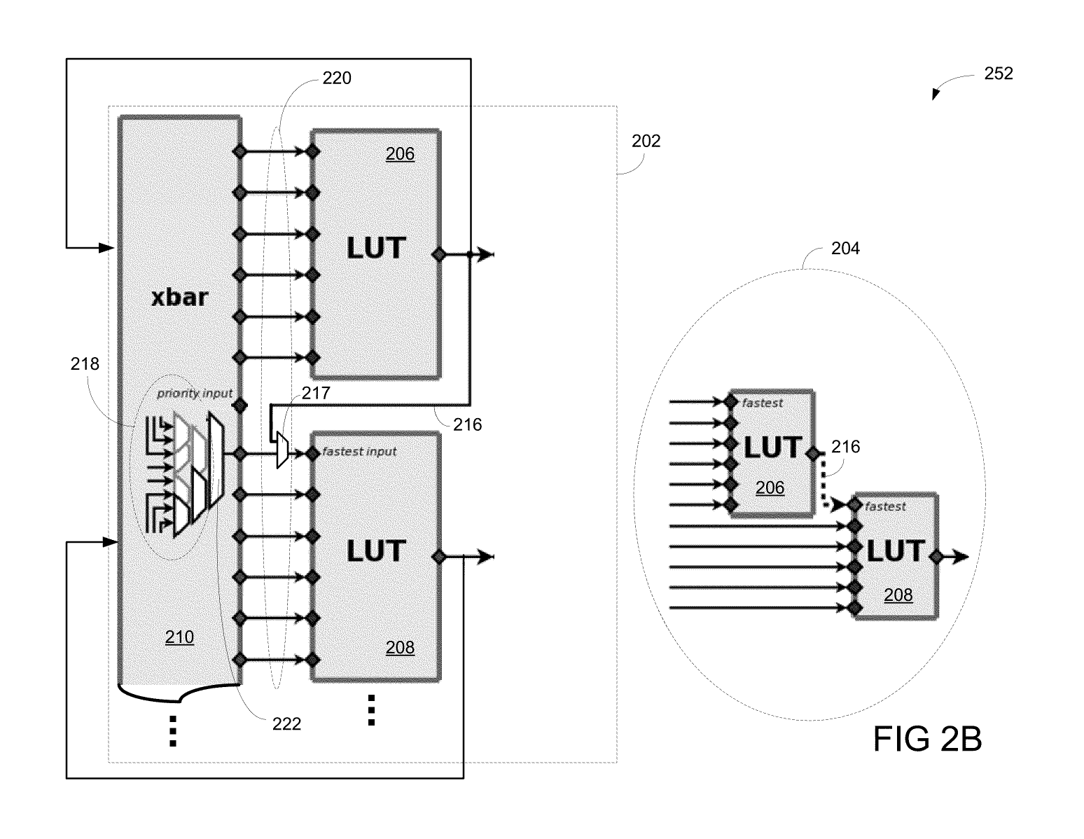

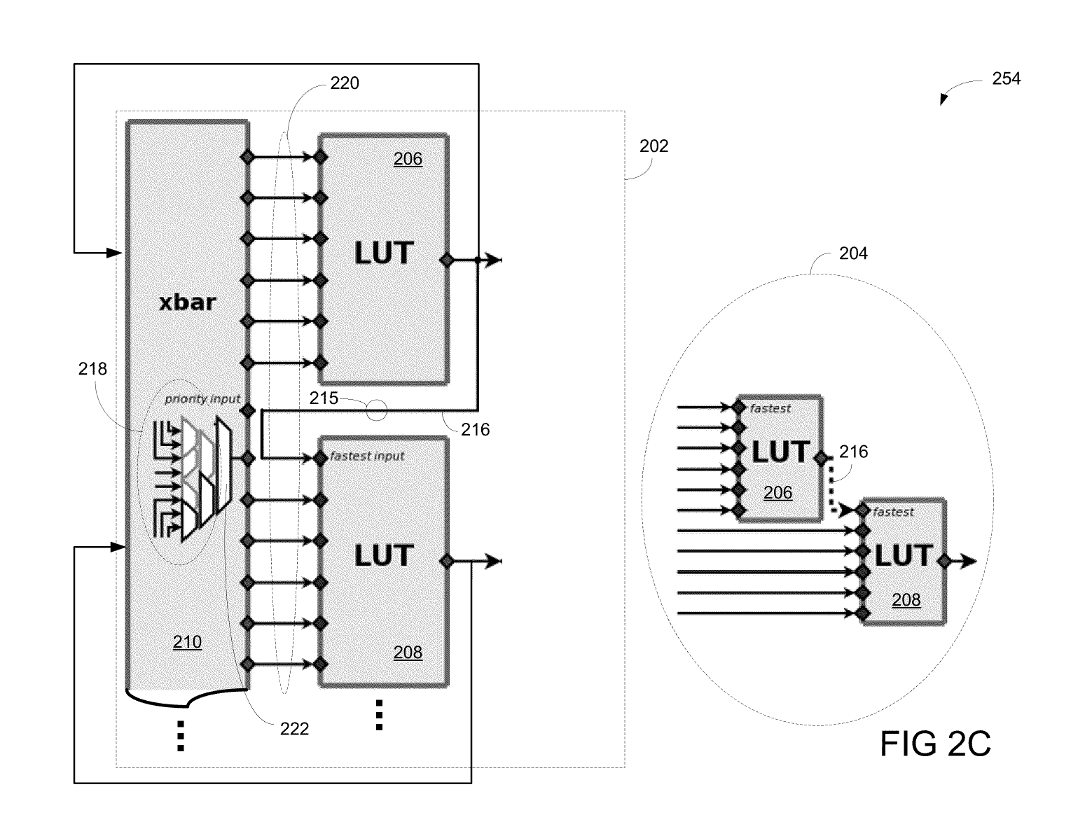

FIGS. 2A-C are block diagrams 250-254 illustrating a cascade configuration using two six-input terminals LUTs in accordance with one embodiment of the present invention. Diagram 250 illustrates a layout of a cascade configuration 202 wherein logic cascade 204 illustrates a logical equivalency to cascade configuration 202. Cascade configuration 202 includes two six-input terminals LUTs 206-208, PIB or crossbar (“xbar”) 210, and a DPW 216. In one example, xbar 210 is part of PIB as discussed in FIGS. 1A-B. Note that cascade configuration 202 and logic cascade configuration 204 are logically as well as functionally equivalent. It should be noted that the underlying concept of the exemplary embodiment(s) of the present invention would not change if one or more blocks (or devices) were added to or removed from diagram 200.

LUTs 206-208, in one example, are basic LUTs having a width of 6-inputs or six-input terminals and one (1) output terminal. A LUT with six-inputs is also known as “LUT6”. Similarly, a five-input LUT can be referred to as a “LUT5” and four-input LUT is referred to as “LUT4,” and so on. To simplify forgoing discussion, LUT6 or LUT with six-inputs are used as an exemplary illustration for describing embodiment(s) of present application. The terms LUT6 six-input terminal LUT, and six-input LUT are directed the same or similar LUTs and hereinafter referred interchangeably. It should be noted that LUT5 and LUT 4 can be equally applied.

PLB 106, as shown in FIG. 1, includes a group of LUTs having a range anywhere from four (4) to sixty-four (64) LUTs. LUTs, in one aspect, are grouped into several groups. Each group, for example, may include two to five LUTs wherein certain input terminals and output terminals of LUTs can be programmably coupled by DPWs and xbar. PIB 210 is routing resource and can be used together with a set of DPWs to connect LUTs in one or more cascade configurations. For example, DPW 216 can be programmed to connect output terminal of LUT 206 to the fastest input terminal of LUT 208. Active refers to as conductive, connecting, and/or active-state. Active state, for example, indicates that a current travel from one end of DPW to another end of DPW. Inactive state, on the other hand, indicates that DPW 216 is open and no current can travel through DPW 216.

Cascade configuration 202 illustrates two LUT6 that are connected in a cascade formation using DPW 216. Cascade configuration 202 provides the functionality up to the functionality of an eleven (11) input terminal LUT with fast delay using two LUT6. Typically, the delay of cascade configuration 202 using DPW 216 is much faster than the delay of two LUT6 connected through generic PIB. An eleven-input terminal LUT means that it is capable of performing eleven-input function(s). For instance, cascade configuration 202 should be able to perform most functions in an eleven-input truth table. Cascade configuration 202 illustrates a layout formation wherein two LUT6 are connected in cascade formation using input DPW 216. It should be noted that DPW 216 can also be used as a part of PIB 210 to facilitate cascade formation.

In one embodiment, DPW 216 is a pre-fabricated direct programmable hardwired connection capable of connecting the output of LUT 206 to the fastest input terminal of LUT 208. The fastest input terminal of LUT, in one aspect, means that a signal at the fastest input terminal of LUT can reach its logic operation level faster than any other input terminals of LUT. Also, the 2^{nd} fastest input terminal of LUT, in one aspect, means that a signal at the 2^{nd} fastest input terminal of LUT can reach its logic operation level faster than any other input terminals of LUT except the fastest input terminal of LUT.

The advantage of using a direct programmable hardwired connection is that it provides high speed with minimal delay. LUT 206 is able to receive six (6) input signals while LUT 208 is able to receive five (5) input signals wherein the fastest input terminal of LUT 208 is dedicated for the cascade configuration. In one example, cascade configuration 202 is able to perform an eleven (11)-input function according to input signals from the programmable interconnect fabric or PIB.

The general interconnect fabric or PIB 210 is constructed with multiple levels of muxes for routing signals including internal routing between LUTs. Internal routing means routing within a PLB. In one example, xbar 210 is part of PIB and the last level of multiplexing 218 is physically and/or logically near LUTs such as LUT 208. An additional input branch or priority mux 222 is added to the last level of multiplexing 218 for the cascade configuration. As such, a cascade configuration for LUTs 206-208 is accomplished when output terminal of LUT 206 is coupled to the fastest input terminal of LUT 208 via DPW 216 and priority mux 222.

The advantage of using priority mux 222 is that it is simple to insert and the delay is minimal comparing with the rest of multiplexing structure in xbar 210 or PIB. In addition, the utility for normal LUT6 function can still be achieved. Another advantage of using cascade configuration using DPW is that when cascading adjacent LUTs is available, logic-mapping step can be achieved by treating small groups of LUTs as monotonic as well as wider LUT(s) capable of realizing complex functions.

Diagram 252 of FIG. 2B illustrates an alternative configuration of cascading LUTs 206-208 using DPW 216. For example, a mux or custom mux 217 is inserted in front of the fastest input terminal of LUT 208, also known as downstream LUT, to control whether a cascade configuration is selected. An advantage of using mux 217 is that it can recover full usage of its inputs when the wider function is not selected. Although the added mux such as mux 217 introduces additional delay, this delay is usually minimal comparing with the delay generated by the rest of multiplexing structures in PIB 210.

Diagram 254 of FIG. 2C illustrates another alternative configuration of cascading LUTs 206-208 using DPW 216. DPW 216, in one embodiment, is a wire that is permanently connected between the output of LUT 206 and the fastest input terminal of LUT 205. If DPW 216 is a wire, it simplifies cascade formation design but it is less flexible. Alternatively, DPW 216 is a programmable wire controlled by a control element or memory cell 215. The advantage of using memory cell 215 is that LUT 206 and LUT 208 can be used as two independent LUT when memory cell 215 deactivates DPW 216.

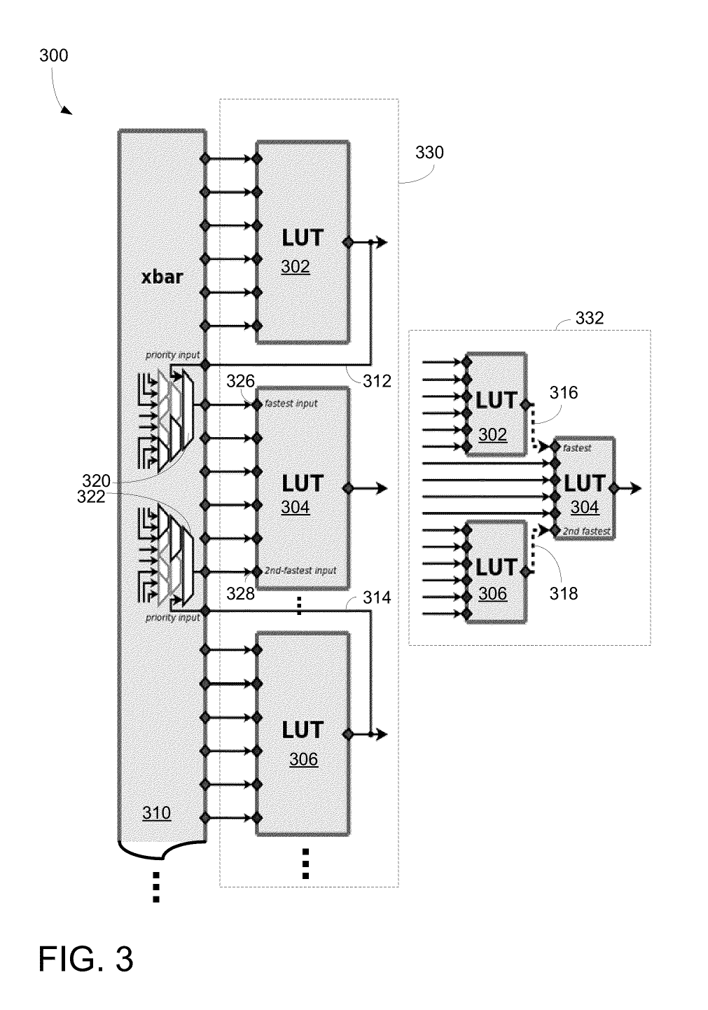

FIG. 3 is a block diagram 300 illustrating an alternative layout of cascade configuration showing a convergent approach using two priority inputs in accordance with one embodiment of the present invention. Diagram 300 includes a PIB (or xbar) 310 and cascade configuration 330 wherein logic cascade configuration 332 illustrates a logical equivalency to cascade configuration 330. PIB 310 includes multiple level of multiplexing for routing signals. It should be noted that the underlying concept of the exemplary embodiment(s) of the present invention would not change if one or more blocks (or devices) were added to or removed from diagram 300.

Cascade 330 includes three (3) LUTs 302-306 wherein LUT 304 includes the fastest input terminal 326 and 2^{nd} fastest input terminal 328. The output of LUT 302 is fed to the fastest input terminal 326 of LUT 304 via DPW 312, and the output of LUT 306 is fed to the second fastest input terminal 328 of LUT 304 via DPW 314. It should be noted that DPWs 312-314 can be direct wires or programmable wires capable of providing high speed connections between outputs of LUTs 302, 306 and inputs of LUT 304.

To forming LUTs into cascade configuration, two muxes can be added to the fastest and 2^{nd} fastest input terminals 326-328 for connecting LUTs 302-306. For example, one end of DPW 312 is coupled to output of LUT 302 and another end of DPW 312 is coupled to one input of the mux which is further coupled to the fastest input terminal 326 of LUT 304. Similarly, one end of DPW 314 is coupled to output of LUT 306 and another end of DPW 312 is coupled to one input of another mux which is further coupled to the 2^{nd} fastest input terminal 328 of LUT 304.

Alternatively, inserting two priority muxes 320-322 at the last layer of multiplexing of PIB 310 is another implementation to couple outputs of LUTs 302 and 306 to 1st and 2^{nd} input terminals of LUT 304. In other words, 1^{st} and 2^{nd} priority inputs are generated in PIB 310 for facilitating formation of cascade configuration. To generate a cascade configuration, DPW 312 is used to route the output from LUT 302 to fastest input terminal 326 of LUT 304 via mux 320 and route the output from LUT 306 to 2^{nd} input terminal 328 of LUT 304 via mux 322.

An advantage of using a convergent cascade formation is that cascade configuration 330 or 332 can handle up to 16-input function with fast delay. Typically, the delay of cascade configuration 330 or 332 using three (3) LUT6 connected by DPW(s) is much faster than the delay of three (3) LUT6 connected through generic PIB. Another advantage of using the convergent cascade formation is that cascade 330 occupies less silicon or die area than the die area needed to fabricate a 16-input terminals LUT.

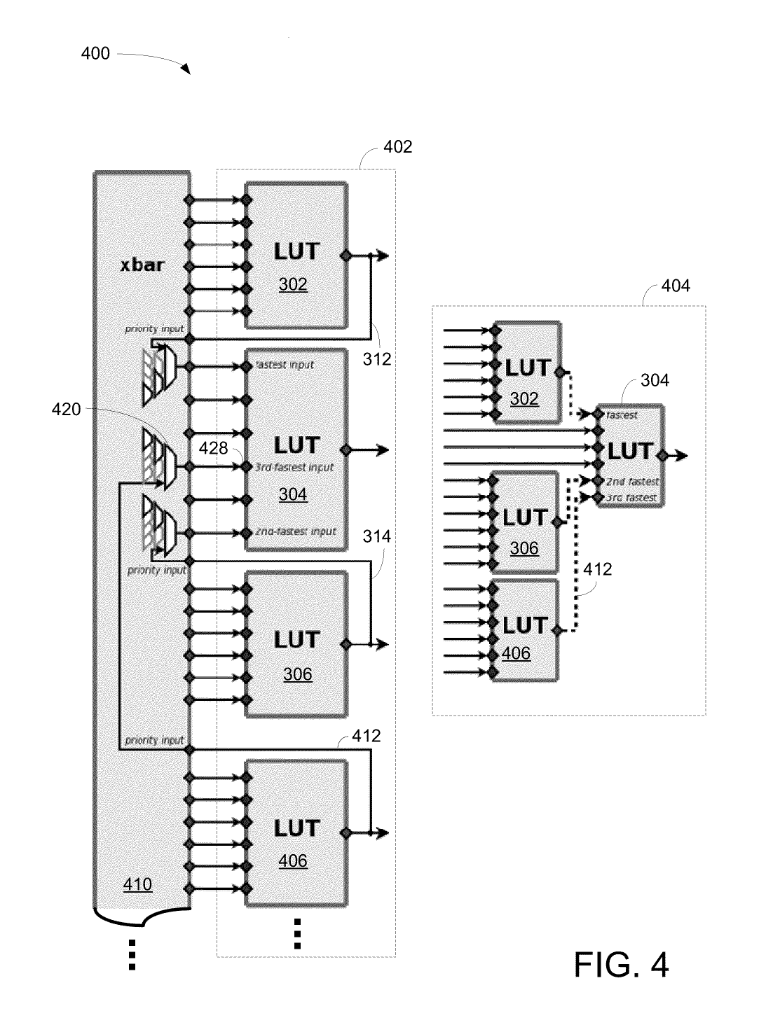

FIG. 4 is a block diagram 400 illustrating an alternative layout for a convergent cascade configuration using four (4) six-input terminals LUTs in accordance with one embodiment of the present invention. Diagram 400, which is similar to diagram 300, includes a PIB 410 and cascade configuration 402, wherein logic cascade configuration 404 illustrates a logical equivalency to cascade configuration 402. PIB 410 includes multiple level of multiplexing for routing signals. It should be noted that the underlying concept of the exemplary embodiment(s) of the present invention would not change if one or more blocks (or devices) were added to or removed from diagram 400.

Cascade configuration 402 includes four (4) LUTs 302-306, 406 wherein LUT 304 includes the fastest input terminal, the 2^{nd} fastest input terminal, and the 3^{rd} fastest input terminal 428. While output of LUT 302 is coupled to the fastest input terminal of LUT 304 and output of LUT 306 is coupled to the second fastest input terminal of LUT 304, the output of LUT 406 is fed to the 3^{rd} fastest input terminal 428 of LUT 304 using DPW 412. It should be noted that DPW 412, like DPW 312, can be a direct wire or programmable wire capable of providing a high speed connection between output of LUT 406 and input of LUT 304.

In one embodiment, a mux or multiplexer is added to the 3^{rd} fastest input terminal 428 of LUT 406. To form a cascade configuration between LUTs 304 and 406, DPW 412 is used to connect output of LUT 406 with one input terminal of the mux. Although the added mux can create additional delay, such delay is small comparing to delay generated by PIB 410.

Inserting a priority mux 420 for the 3^{rd} priority input at the last layer of multiplexing in PIB 410 is another implementation to generate a cascade configuration between LUTs 304 and 406. DPW 412, for example, may be used to connect output of LUT 406 to an input of priority mux 420 which is further fed to the 3^{rd} fastest input terminal 428 of LUT 304. Even though added priority mux 420 will generate additional delay, such delay is small comparing to delay generated by PIB 410.

An advantage of using the convergent cascade formation is that cascade configuration 402 can handle up to 21-input function. Typically, the delay of cascade configuration 402 using four (4) LUT6 connected by DPW(s) as mentioned above is much faster than the delay of four (4) LUT6 connected through generic PIB. Another advantage of using the convergent cascade formation is that cascade configuration 402 takes less die area than the area needed to fabricate a 21-input LUT. For instance, to compare die size between a single LUT with 21-inputs (“LUT21”) and LUT6, LUT21 would be 32,000 times the size of a LUT6.

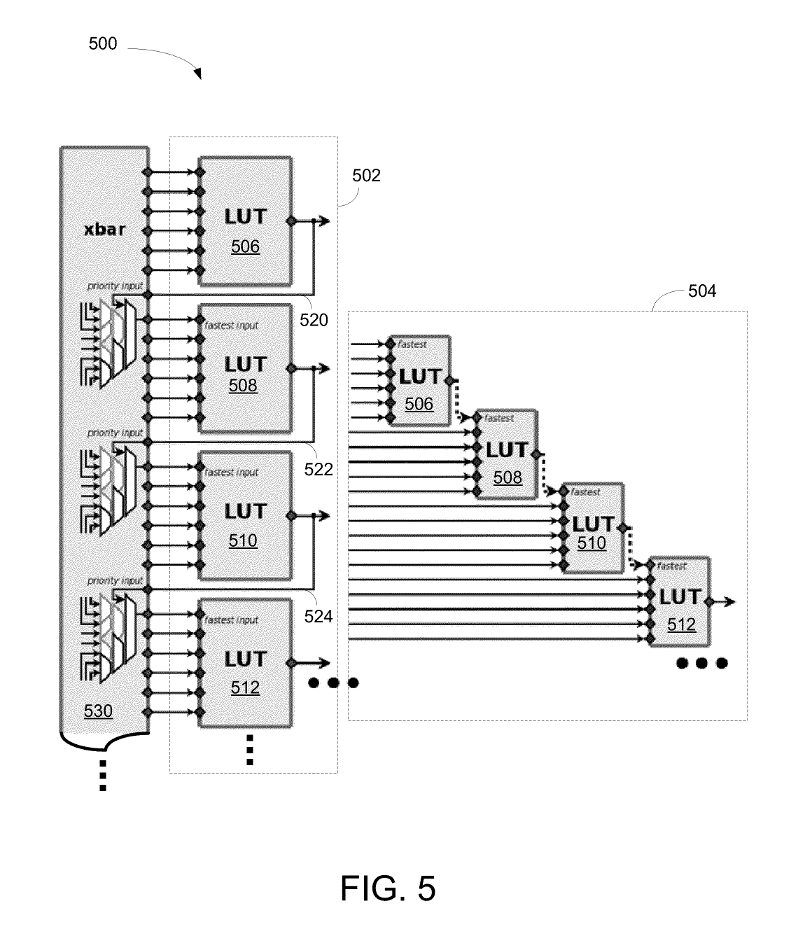

FIG. 5 is a block diagram 500 illustrating a cascade configuration organized in a continuous chain formation in accordance with one embodiment of the present invention. Diagram 500, similar to diagram 400, includes a PIB or xbar 530, a cascade configuration 502 wherein logic cascade configuration 504 illustrates a logical equivalence to cascade configuration 502. PIB 530 includes multiple level of multiplexing for routing signals. It should be noted that the underlying concept of the exemplary embodiment(s) of the present invention would not change if one or more blocks (or devices) were added to or removed from diagram 500.

Cascade configuration 502 includes four (4) LUTs 506-512 wherein LUTs 508-512 include the fastest input terminals. To forming a chain cascade, output of LUT 506 is fed to the fastest input terminal of LUT 508 via DPW 520, and output of LUT 508 is fed to the fastest input terminal of LUT 510 via DPW 522. After connecting output of LUT 510 to the fastest input terminal of LUT 512 via DPW 524, a cascade configuration with a continues chain is formed. It should be noted that DPWs 520-524 can be direct wires or programmable wires able to provide high speed connections between the outputs of LUTs and inputs of LUTs. Depending on the applications, additional LUTs can be chained in configuration 502 to achieve a desirable function.

It should be noted that extending the cascade pattern into a long chain is a method to realize various logic functions with large number of inputs. An advantage of using a cascade with a chain formation is to increase placement flexibility for performing complex functions.

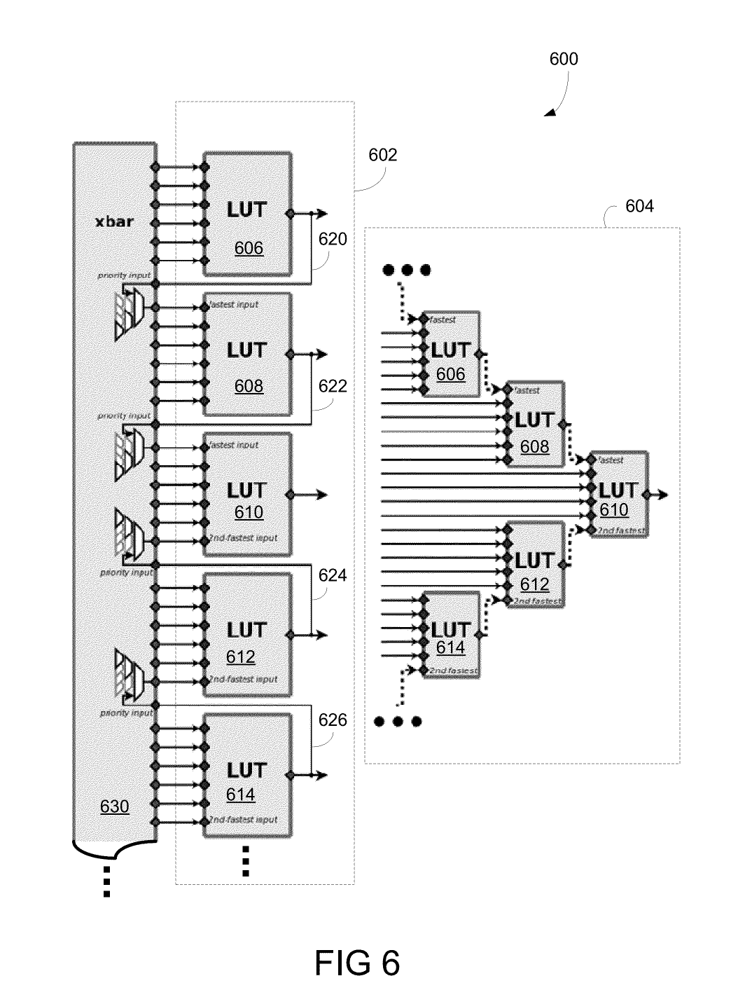

FIG. 6 is a diagram 600 illustrating a multi-level convergent cascade for programmable LUTs in accordance with one embodiment of the present invention. Diagram 600, similar to diagram 300, includes a PIB or xbar 630 and cascade configuration 602 wherein logic cascade configuration 604 illustrates a logical equivalency to cascade configuration 602. PIB 630 includes multiple level of multiplexing for routing signals. It should be noted that the underlying concept of the exemplary embodiment(s) of the present invention would not change if one or more blocks (or devices) were added to or removed from diagram 600.

Cascade configuration 602 includes five (5) LUTs 606-614 which include the fastest and 2^{nd} fastest input terminals. In one aspect, the output of LUT 606 is fed to the fastest input terminal of LUT 608 via DPW 620, and the output of LUT 608 is fed to the fastest input terminal of LUT 610 via DPW 622. The output of LUT 614 is fed to the 2^{nd} fastest input terminal of LUT 612 via DPW 626 and the output of LUT 612 is fed to the 2^{nd} fastest input terminal of LUT 610 via DPW 624. It should be noted that DPWs 620-626 can be wires and/or programmable wires able to provide high speed connections.

Cascade configuration 602 provides chains in opposite directions, one “up” and one “down” logical layout used to have large number of inputs of LUTs to converge at fifth LUT with minimal delay. Note that the opposite direction or “up” and “down” means logical opposite side with respect to LUT 610. For example, LUT 606 is at “up” chain and in opposite direction to LUT 614 which is situated at “down” chain. LUTs 606-614 provide up to 26 independent inputs. LUTs 606-614, in one embodiment, are able to substantially perform functions up to a 26-input truth table.

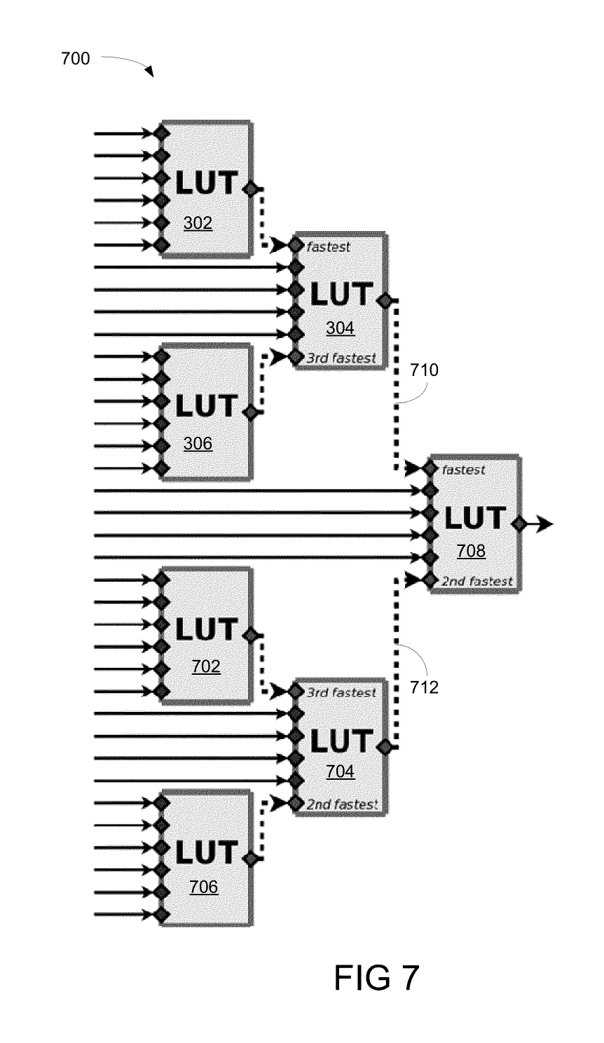

FIG. 7 is a diagram 700 illustrating a layout of two 3-LUT groups converging onto a seventh LUT in accordance with one embodiment of the present invention. Diagram 700, which is similar to diagram 300, includes seven (7) LUTs 302-306 and 702-708 configured in a three layer LUT cascade configuration. Note that LUTs 702-706 are organized similar to LUTs 302-306 as described in FIG. 3. LUT 708, which includes fastest input terminal and 2^{nd} fastest input terminal, is used to link the two groups of LUTs containing LUTS 302-306 and 702-706. For example, the output of LUT 304 is fed to fastest input terminal of LUT 708 via DPW 710, and the output of LUT 704 is fed to second fastest input terminal of LUT 708 via DPW 712. It should be noted that DPWs 710-712 can be wires or programmable wires capable of providing high speed connection.

An advantage of using two 3-LUT groups converging on a seventh LUT is that LUTs 302-306 and 702-708 are capable of handling up to 36 independent inputs. As such, LUTs 302-306 and 702-708 are able to perform the functionality up to a 36-input truth table with very fast delay comparing with the LUTs connected through generic PIB.

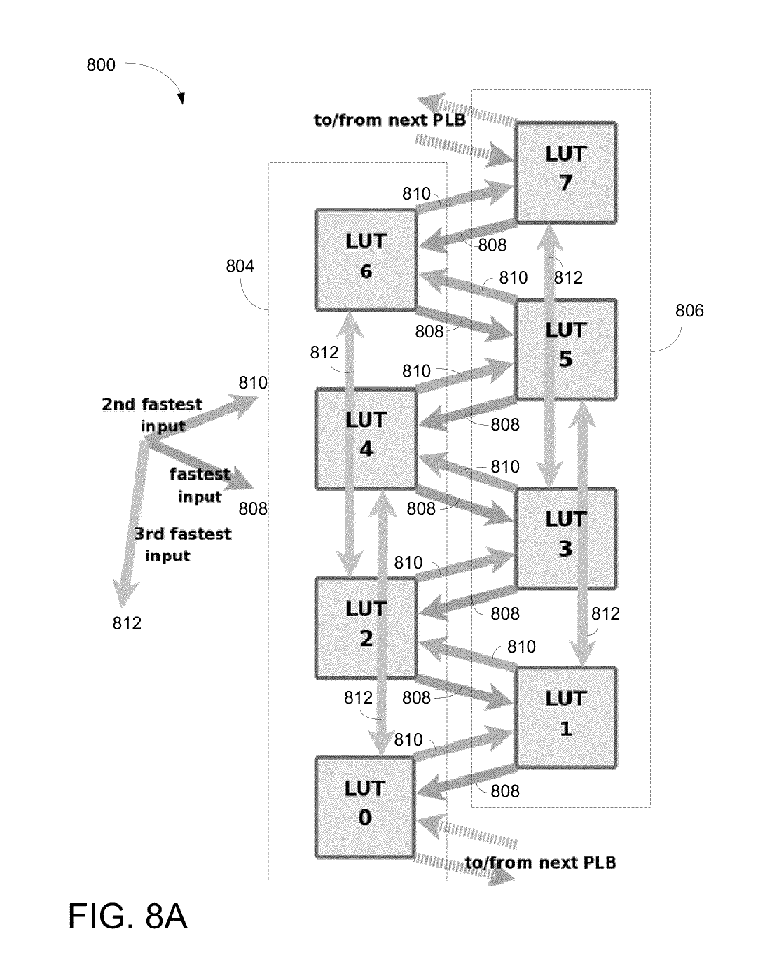

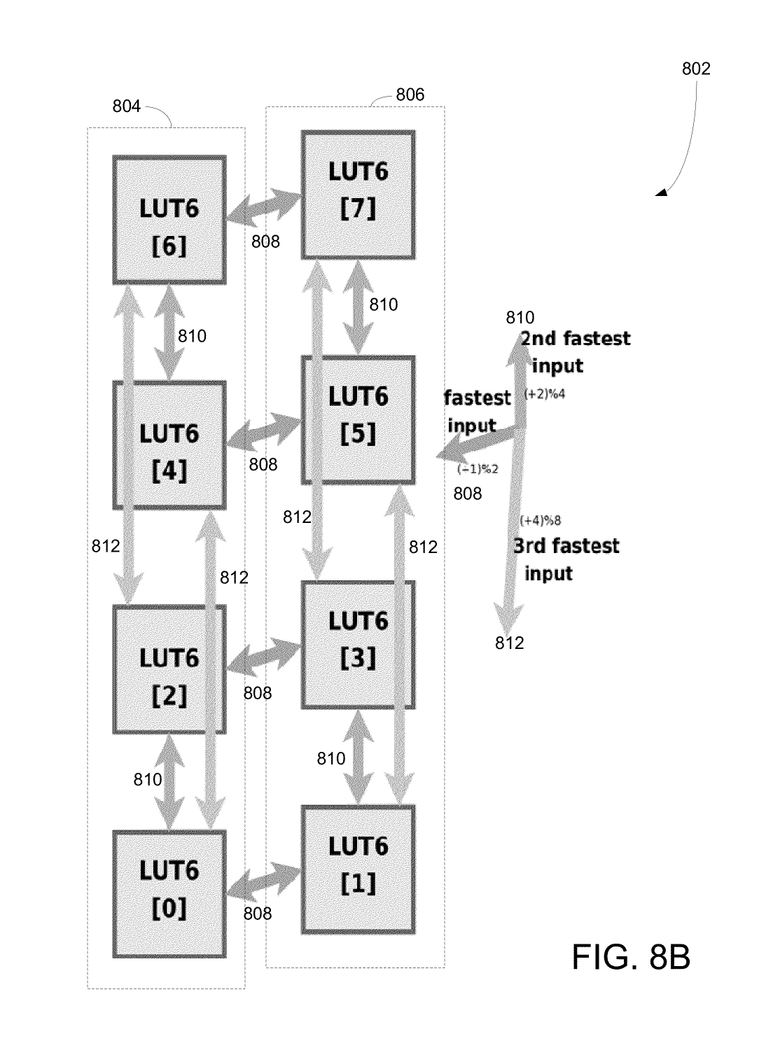

FIGS. 8A-B are block diagrams 800-802 illustrating cascade maps or logical layout within PLB logic in accordance with one embodiment of the present invention. Diagram 800 includes a PLB having two banks 804-806 of LUTs wherein LUT 0, 2, 4, 6 are in bank 804 and LUT 1, 3, 5, 7 are in bank 806. A set of predefined fastest programmable input connections (“PICs”) 808 is used for generating cascade configurations. For example, fastest PICs 808 are available for connection from LUT7 to LUT6, LUT6 to LUT5, LUT5 to LUT4, and so on. Also, a set of predefined 2^{nd} fastest PICs 810 are used to provide the 2^{nd} fastest input connections. For example, the 2^{nd} fastest PICs 810 are available for connection from LUT0 to LUT1, LUT1 to LUT2, LUT2 to LUT3, and so. Another set of predefined 3^{rd} fastest PICs 812 are used to provide 3^{rd} fastest input connections. For example, the 3^{rd} fastest PICs 812 are available within the bank. For instance, LUT0 can connect to LUT4 using a 3^{rd} fastest PIC 812 for connection.

Diagram 802 illustrates an alternative layout showing two banks 804-806 of LUTs wherein LUT 0, 2, 4, 6 are in bank 804 and LUT 1, 3, 5, 7 are in bank 806. A set of predefined fastest programmable input connections (“PICs”) 808 is used for fast connection. For example, fastest PICs 808 are available between LUT7 and LUT6, LUT5 and LUT4, LUT3 and LUT2, and LUT1 and LUT0 as illustrated in diagram 802 for fast connections. Also, a set of predefined 2^{nd} fastest PICs 810 are used to provide 2^{nd} fastest input connections. For example, the 2^{nd} fastest PICs 810 are available between LUT0 and LUT2, LUT1 and LUT3, LUT4 and LUT6, LUT5 and LUT7 for connections to generate cascade configurations. Another set of predefined 3^{rd} fastest PICs 812 are used to provide 3^{rd} fastest input connections. For example, the 3^{rd} fastest PICs 812 are available within the bank. For instance, LUT0 can connect to LUT4 using a 3^{rd} fastest PIC 812 for connection, and LUT1 can connect to LUT5 using a 3^{rd} fastest PIC 812 for connection.

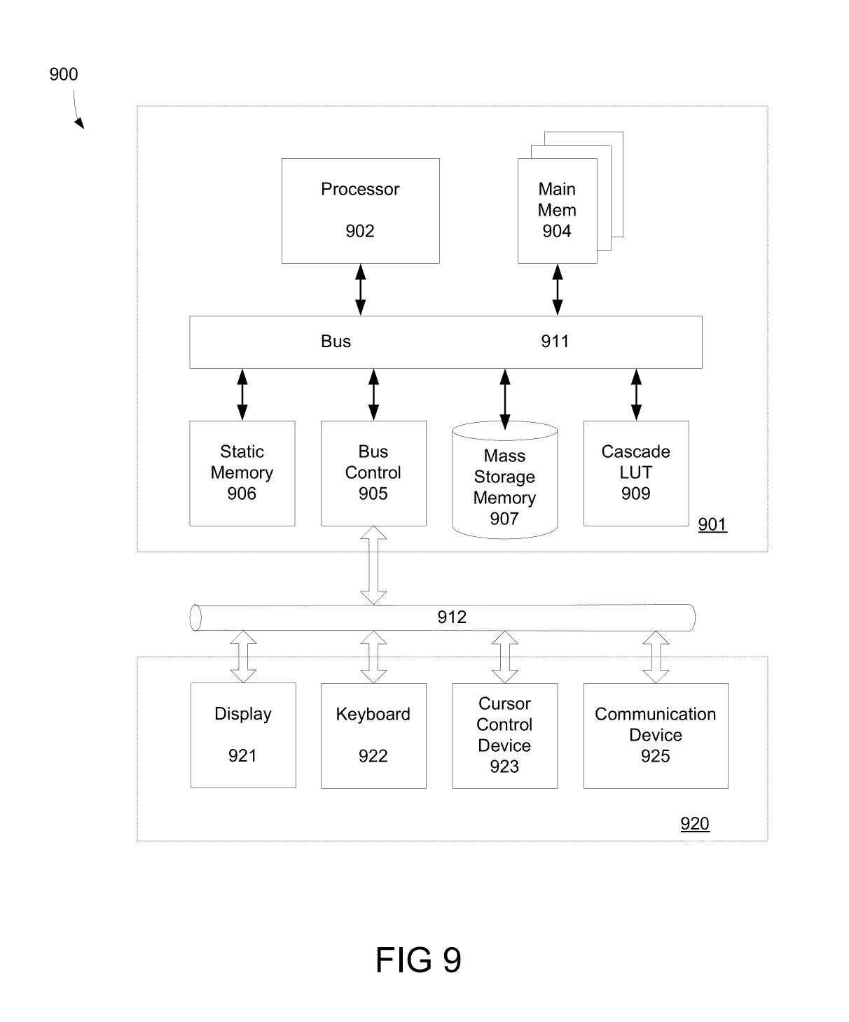

Having briefly described one or more embodiments of cascade configuration for LUTs to perform programmable functions in which the present invention operates, FIG. 9 illustrates an example of a digital computing system 900, which may be used in a network system or personal computing, in which the features of the present invention may be implemented.

FIG. 9 is a diagram illustrating an example of digital processing system including programmable IC device using LUT cascade configuration in accordance with one embodiment of the present invention. Computer system 900 includes a processing unit 901, an interface bus 911, and an input/output (“IO”) unit 920. Processing unit 901 includes a processor 902, a main memory 904, a system bus 911, a static memory device 906, a bus control unit 905, a mass storage memory 907, and programmable IC 909. Programmable IC 909 is able to provide programmable functions with multiple inputs using cascade configurations. It should be noted that the underlying concept of the exemplary embodiment(s) of the present invention would not change if one or more blocks (circuit or elements) were added to or removed from diagram 900.

Bus 911 is used to transmit information between various components and processor 902 for data processing. Processor 902 may be any of a wide variety of general-purpose processors, embedded processors, or microprocessors such as ARM® embedded processors, Intel® Core™ 2 Duo, Core™ 2 Quad, Xeon®, Pentium™ microprocessor, Motorola™ 68040, AMD® family processors, or Power PC™ microprocessor.

Main memory 904, which may include multiple levels of cache memories, stores frequently used data and instructions. Main memory 904 may be RAM (random access memory), MRAM (magnetic RAM), or flash memory. Static memory 906 may be a ROM (read-only memory), which is coupled to bus 911, for storing static information and/or instructions. Bus control unit 905 is coupled to buses 911-912 and controls which component, such as main memory 904 or processor 902, can use the bus. Bus control unit 905 manages the communications between bus 911 and bus 912. Mass storage memory 907, which may be a magnetic disk, an optical disk, hard disk drive, floppy disk, CD-ROM, and/or flash memories are used for storing large amounts of data.

I/O unit 920, in one embodiment, includes a display 921, keyboard 922, cursor control device 923, and communication device 925. Display device 921 may be a liquid crystal device, cathode ray tube (“CRT”), touch-screen display, or other suitable display device. Display 921 projects or displays images of a graphical planning board. Keyboard 922 may be a conventional alphanumeric input device for communicating information between computer system 900 and computer operator(s). Another type of user input device is cursor control device 923, such as a conventional mouse, touch mouse, trackball, or other type of cursor for communicating information between system 900 and user(s).

Communication device 925 is coupled to bus 911 for accessing information from remote computers or servers, such as server or other computers, through wide-area network. Communication device 925 may include a modem or a network interface device, or other similar devices that facilitate communication between computer 900 and the network.

The exemplary aspect of the present invention includes various processing steps, which will be described below. The steps of the aspect may be embodied in machine or computer executable instructions. The instructions can be used to direct a general purpose or special purpose system, which is programmed with the instructions, to perform the steps of the exemplary aspect of the present invention. Alternatively, the steps of the exemplary aspect of the present invention may be performed by specific hardware components that contain hard-wired logic for performing the steps, or by any combination of programmed computer components and custom hardware components.

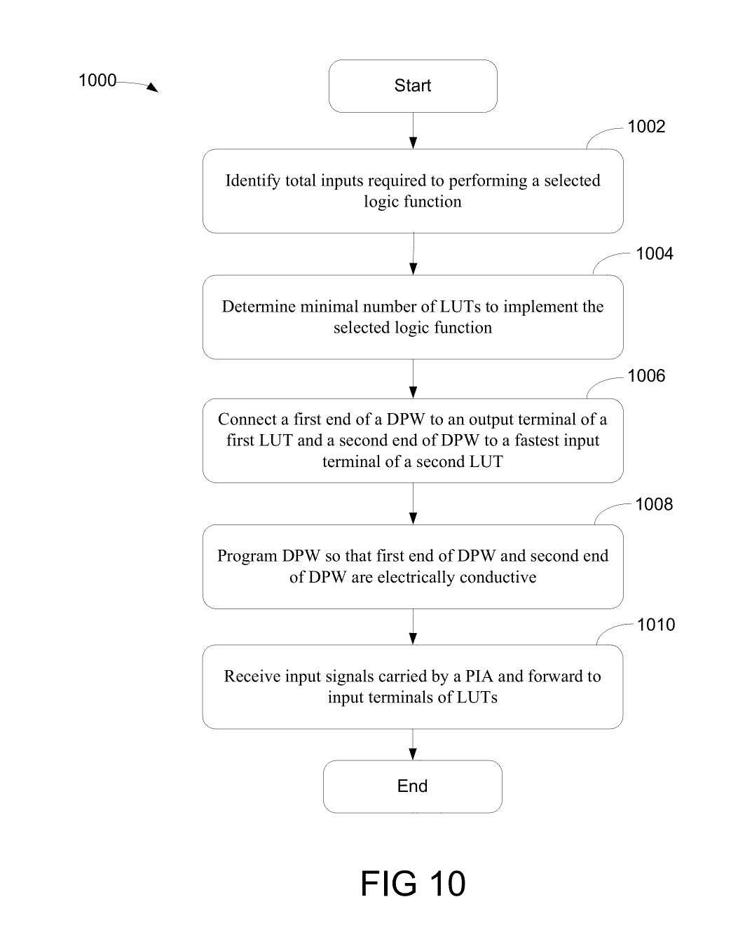

FIG. 10 is a flow chart illustrating a process of cascading multiple LUTs using dedicated connections to perform logic functions in accordance with one embodiment of the present invention. At block 1002, a method able to cascade LUTs identifies total number of inputs required to performing a selected logic function. For example, the process is able to receive a user selected logic function at a PLB and subsequently determines minimal number of LUTs needed to perform the logic function.

At block 1004, the minimal number of LUTs is determined for implementing the selected logic function. In one aspect, the process is capable of identifying number of LUTs with one output-terminal and four input-terminals or LUT4 required performing the selected logic function.

At block 1006, one end of DPW is used to connect output terminal of first LUT and second end of DPW connects to the fastest input terminal of second LUT. Note that first LUT and second LUT are amount of minimal number of LUTs.

At block 1008, the process is capable of programming the DPW to a conducting state or to a non-conducting state. For example, a conducting state means that a current can enter the first end of DPW and exit at the second end of DPW. A non-conducting state means that no current can flow through a DPW.

At block 1010, the process is able to receive input signals transmitted or carried from PIB by the input terminals of minimal number of LUTs. An output signal generated by an output terminal of a LUT is forwarded to its destination via a second DPW. In one example, a first end of a second DPW is connected to an output terminal of a third LUT and a second end of the second DPW is connected to a second fastest input terminal of the second LUT. Note that the first, second, and third LUTs are amount minimal number of LUTs. The process is further capable of identifying number of LUT6 (6-input terminals) required to perform the selected logic function.

While particular embodiments of the present invention have been shown and described, it will be obvious to those of ordinary skills in the art that based upon the teachings herein, changes and modifications may be made without departing from this exemplary embodiment(s) of the present invention and its broader aspects. Therefore, the appended claims are intended to encompass within their scope all such changes and modifications as are within the true spirit and scope of this exemplary embodiment(s) of the present invention.

What is claimed is:

1. An integrated circuit (“IC”) device, comprising:
a programmable logic block (“PLB”) configured to have at least two programmable look-up tables (“LUTs”) and able to perform a logic function programmed by a user, wherein the LUTs are connected in a cascade configuration via a dedicated programmable wire (“DPW”) when the DPW is programmed to a conductive state; and
a first set of programmable interconnection blocks (“PIBs”) coupled to the PLB and configured to selectively route signals from the PLB.

2. The device of claim 1, wherein each of the LUTs includes an output terminal and a plurality of input terminals wherein at least one of the plurality of input terminals is a fastest input terminal with an electrical characteristic of high speed signaling.

3. The device of claim 2,
wherein the DPW includes a first end and a second end;
wherein the LUTs includes a first LUT and a second LUT; and
wherein the first end of the DPW is coupled to an output terminal of a first LUT and the second end of the DPW is coupled to the fastest input terminal of a second LUT.

4. The device of claim 3, wherein each of the LUTs includes one output terminal and four (4) input terminals.

5. The device of claim 3, wherein each of the LUTs includes one output terminal and six (6) input terminals.

6. The device of claim 2, wherein each of the LUTs in the cascade configuration further includes a second fastest input terminal and a third fastest input terminal.

7. The device of claim 6, wherein the PLB includes a first LUT, a second LUT, a third LUT, a first DPW, and a second DPW, wherein the first DPW couples an output terminal of the first LUT to fastest input terminal of the third LUT, and the second DPW couples an output terminal of the second LUT to second fastest input terminal of the third LUT.

8. The device of claim 6, wherein the PLB includes a range of 8 to 64 LUTs having a plurality of fastest DPWs, a plurality of second fastest DPWs, and a plurality of third fastest DPWs.

9. The device of claim 8,
wherein the plurality of fastest DPWs are configured to optionally connect output terminals of LUTs to fastest input terminals of LUTs;
wherein the plurality of second fastest DPWs are configured to optionally connect output terminals of LUTs to second fastest input terminals of LUTs; and
wherein the plurality of third fastest DPWs are configured to optionally connect output terminals of LUTs to third fastest input terminals of LUTs.

10. A system capable of processing digital information comprising the device of claim 1.

11. A method of configuring logic blocks in a cascade configuration, comprising:
identifying total inputs required to performing a selected logic function;
determining minimal number of look-up tables (“LUTs”) to implement the selected logic function;
connecting a first end of a first dedicated programmable wire (“DPW”) to an output terminal of a first LUT of the minimal number of LUTs and a second end of the first DPW to a fastest input terminal of a second LUT of the minimal number of LUTs;
programming the first DPW so that the first end of the first DPW and the second end of the first DPW are electrically conductive; and
receiving input signals carried by a first programmable interconnection array (“PIA”) and forwarding to a plurality of input terminals of the minimal number of LUTs.

12. The method of claim 11, further comprising forwarding an output signal generated by an output terminal of a LUT of the minimal number of LUTs to its destination via a second PRC.

13. The method of claim 12, further comprising connecting a first end of a second DPW to an output terminal of a third LUT of the minimal number of LUTs and a second end of the second DPW to a second fastest input terminal of the second LUT of the minimal number of LUTs.

14. The method of claim 11, wherein identifying total inputs required to performing a selected logic function further includes receiving the selected logic function at a programmable logic block (“PLB”) by a user.

15. The method of claim 11, wherein determining minimal number of look-up tables (“LUTs”) includes identifying number of one (1) output terminal and four (4) input terminals LUTs required to perform the selected logic function.

16. The method of claim 11, wherein determining minimal number of look-up tables (“LUTs”) includes identifying number of one (1) output terminal and six (6) input terminals LUTs required to perform the selected logic function.

17. An integrated circuit (“IC”) device, comprising:
a plurality of input output (“I/O”) blocks configured to selectively couple to a plurality of I/O pads;
a plurality of programmable interconnection blocks (“PIBs”) coupled to the plurality of I/O blocks and able to selectively coupled to at least a portion of the plurality of I/O blocks; and
a plurality of programmable logic blocks (“PLBs”) coupled to the plurality of PIBs, and able to perform selectable logic functions, wherein each of the plurality of PLBs is configured to have at least two programmable look-up tables (“LUTs”), wherein the programmable LUTs are connected in a cascade configuration via a dedicated programmable wire (“DPW”) when the DPW is programmed to a conductive state.

18. The device of claim 17, wherein each of the LUTs includes an output terminal and a plurality of input terminals wherein at least one of the plurality of input terminals is a fastest input terminal with an electrical characteristic of high speed signaling.

19. The device of claim 18,
wherein the DPW includes a first end and a second end;
wherein the LUTs includes a first LUT and a second LUT; and
wherein the first end of the DPW is coupled to an output terminal of a first LUT and the second end of the DPW is coupled to the fastest input terminal of a second LUT.

20. The device of claim 19, wherein each of the LUTs includes one output terminal and four (4) input terminals.
